(19) United States
(12) Patent Application Publication
(10) Pub. No.: US 2006/0157859 A1
(43) Pub. Date: Jul. 20, 2006

(54) LED PACKAGING METHOD AND PACKAGE STRUCTURE

(76) Inventor: Chih-Chen Chou, Miaoli (TW)

Correspondence Address: PAI PATENT & TRADEMARK LAW FIRM, 1001 FOURTH AVENUE, SUITE 3200, SEATTLE, WA, 98154, US

(21) Appl. No.: 11/160,130

(22) Filed: Jun. 10, 2005

(30) Foreign Application Priority Data
Jan. 19, 2005 (TW) 94101535

(51) Int. Cl. H01L 23/48

(52) U.S. Cl. 257/762

(57) ABSTRACT

A LED packaging method is disclosed. The LED packaging method includes the steps of forming a high reflectivity alloy layer on an electrode layer of a support; coating a polymer adhesive on a portion of the upper surface of the high reflectivity alloy layer to form an adhering point; and fixing a chip on the adhering point and baking the chip, wherein the polymer adhesive includes an epoxy resin and at least one of acid anhydride and amine.

### BACKGROUND OF THE INVNETION

a) Field of the Invention

The invention relates to a LED structure and method for manufacturing the same and, more particularly, to a LED packaging method and package structure.

b) Description of the Related Art

Light emitting diode (LED) has been gradually applied to different fields since it was invented, and today, it plays a very important role in our daily lives. In the past, LED is mostly used in indicator signal lights due to lack of brightness. However, with the advancements in LED technology and chip manufacturing technology, the usage of LED is more diversified.

As the brightness of LED increases, so does the heat generated by LED. Hence, the heat dissipation capability and luminous efficiency of LED package structure become very important for further enhancing the luminous efficiency of high power LED chips. Especially, the heat dissipation capability of LED package structure is crucial to the successful package of chips with a size greater than 24 mil.

A conventional method to package LED is shown in FIG. 1, where a chip 100 is bonded to an electrode layer 104 of a support 103 by an adhesive 102. The adhesive 102 is usually a mixture of epoxy resin and metal powder (commonly silver) at a ratio of 2:3. This type of adhesives is provided to fix chips taking advantage of the high-temperature-hardening property of epoxy resin. In addition, silver powder is added therein to conduct electricity and heat. However, this conventional LED packaging method is not suitable for high brightness LED because these adhesives are not good heat conductors, and thereby the heat generated by the chip cannot be effectively dissipated. As shown in FIG. 1, there is a greater distance between an electrode layer 101 of the chip 100 and the electrode layer 104 of the support 103 due to the material property of the adhesive 102. Since the adhesive 102 has larger intermolecular gaps therebetween, its adhesion force is weaker and a stronger pushing/pulling force will not be allowed, which in turn results in poor conductivity between the electrode layers 101 and 104 and reduced luminous efficiency. Moreover, the adhesive 102 is often non-transparent; hence, the luminous efficiency is also lowered.

To overcome the heat dissipation problem, packaging techniques such as flip-chip or flux eutectic have been applied. Nonetheless, the flip-chip packaging method requires expensive equipment and it still leads to poor heat dissipation effect. On the other hand, in the flux eutectic packaging method, the chip is exposed to a temperature higher than 280° C. for eutectically bonding a pad layer on the chip and a metal layer of the support, which damages the chip directly and decreases the yield as well as the life span of the chip. U.S. Pat. No. 6,396,082 has disclosed a conventional LED packaging method. FIG. 2 illustrates the FIG. 2 of the U.S. Pat. No. 6,396,082, in which a flip-chip LED 29, with a transparent substrate facing upward, is fixed on a glass epoxy substrate 22 with silver paste or with a soft soldering layer 37. A through hole 25 is provided in the central area of the glass epoxy substrate 22 substantially directly above the flip-chip LED 29, and two contact holes 23, 24 are formed on the upper surface 26A of the glass epoxy substrate 22. This through hole 25 is filled with a transparent resin, forming a transparent resin layer 27. The flip-chip LED 29 further includes two metal electrodes 33, 34 connected to the contact holes 23, 24 respectively with conducting wires 35, 36, wherein the flip-chip LED 29 and the conducting wires 35, 36 are protected by a resin sealing body 38. The glass epoxy substrate 22 is mounted upside down to a motherboard 41 by fitting the resin sealing body 38 into an insertion hole 42 of the motherboard 41.

In this conventional technology, light emitted from the upside down LED passes through the through hole 25 without being blocked by the metal electrodes 33, 34, and thus this conventional technology provides good light transmission. However, the glass epoxy substrate 22 has excellent insulation property, and the LED 29 is fully covered by the sealing resin layer 27, resulting in that heat generated by the LED 29 can only be dissipated through the contact holes 23, 24. Therefore, this type of substrate packaging element has poor heat dissipation function.

Concluding from the above, the conventional LED packaging methods have flaws such as poor heat dissipation function, poor luminous efficiency, and poor adhesion force. Hence, a novel packaging method is needed to improve the conventional packaging technologies.

### BRIEF SUMMARY OF THE INVENTION

An object of the invention is to provide a high brightness LED packaging method, in which a chip is effectively fixed in cryogenic condition with the use of special polymer material and an alloy layer having a support fixing surface and has good heat dissipation, forming a LED package with great heat dissipation effect.

Therefore, the invention discloses a LED packaging method including steps of: forming a high reflectivity alloy layer on an electrode layer of a support; coating a polymer adhesive on a portion of the upper surface of the high reflectivity alloy layer to form an adhering point; fixing a chip onto the adhering point and baking it at a temperature of 120 to 180° C., wherein the polymer adhesive includes an epoxy resin and at least one of acid anhydride and amine.

The material of the support can be a high heat dissipating metal such as iron, copper, or aluminum, a composite material such as high polymer, thermosetting, thermoplastic metal, ceramic or carbon fiber composite material or a ceramic material substantially composed of clay, cement and glass, and the high reflectivity alloy layer can be gold, silver, nickel, tin or an alloy formed with any two or more of the four listed metals.

The chip includes at least one electrode layer; the anode and cathode of the electrode layer can be on different sides or the same side of the chip. The material of the development system of the chip can be GaN, AlGaN, AlN, GaInN, GaAs, AlInGaP, AlGaInN, InN, GaInAsN, or GaInPN. The alloy layer of the chip can be gold, silver, nickel, tin, or an alloy formed with any two or more of the four listed metals. The range of light and photon energy generated by the chip is between the spectrums of ultraviolet (UV) light and infrared light.

A LED package structure according to another embodiment of the invention includes: an electrode layer on a support, a high reflectivity alloy layer on the electrode layer coated with a polymer adhesive on its upper surface for forming an adhering point, and a chip fixed on the adhering point by baking, wherein the polymer adhesive includes an epoxy resin and at least one of acid anhydride and amine.

The material of the support can be a high heat dissipating metal such as iron, copper or aluminum, a composite material such as high polymer, thermosetting, thermoplastic metal, ceramic or carbon fiber composite material, or a ceramic material substantially composed of clay, cement and glass, and the high reflectivity alloy layer can be gold, silver, nickel, tin, or an alloy formed with any two or more of the four listed metals.

The chip includes at least one electrode layer; the anode and cathode of the electrode layer can be on different sides or the same side of the chip. The material of the development system of the chip can be GaN, AlGaN, AlN, GaInN, GaAs, AlInGaP, AlGaInN, InN, GaInAsN, or GaInPN. The alloy layer of the chip can be gold, silver, nickel, tin, or an alloy formed with any two or more of the four listed metals. The range of light and photon energy generated by the chip is between the spectrums of UV light and infrared light.

### BRIEF DESCRIPTION OF THE DRAWINGS

FIG. 1 illustrates a conventional LED packaging method;

FIG. 2 illustrates another conventional LED packaging method;

FIG. 3 illustrates one step of a LED packaging method according to the invention;

FIG. 4 illustrates one step of a LED packaging method according to the invention;

FIG. 5 illustrates one step of a LED packaging method according to the invention;

FIG. 6 illustrates one step of a LED packaging method according to the invention;

FIG. 7 illustrates a package structure attained by the LED packaging method according to the invention;

FIG. 8 illustrates another package structure attained by the LED packaging method according to the invention

FIG. 9 illustrates a comparison of electrical property of the LED packaging method according to the invention, the conventional LED packaging method with silver paste, and the flux eutectic LED packaging method;

FIG. 10A illustrates the resultant products formed by the LED packaging method according to the invention and the conventional LED packaging method;

FIG. 10B illustrates a resultant product formed by the LED packaging method according to the invention; and

FIG. 10C illustrates a resultant product formed by the conventional LED packaging method.

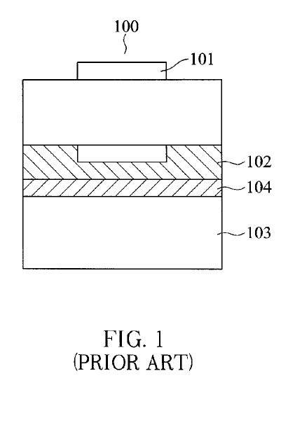

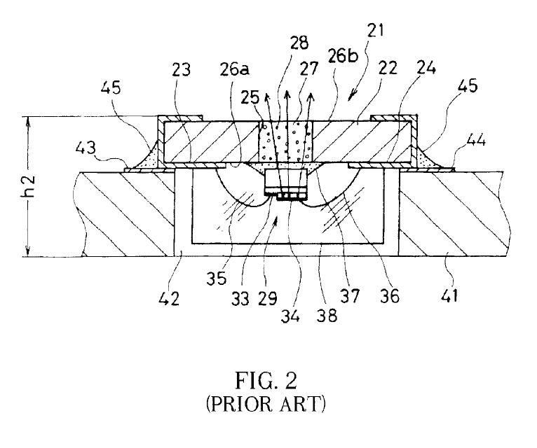

### DETAILED DESCRIPTION OF THE INVENTION

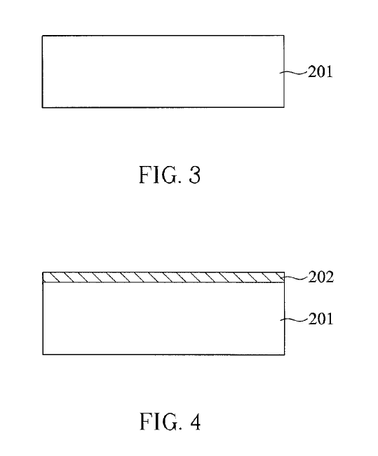

A high brightness LED packaging method according to the invention is described below in detail with reference to the drawings. As shown in FIG. 3, an electrode layer 201 of a support is provided, the material of the support can be a high heat dissipating metal such as iron, copper or aluminum, a composite material such as high polymer, thermosetting, thermoplastic metal, ceramic or carbon fiber composite material or a ceramic material substantially composed of clay, cement and glass. Then, in FIG. 4, a high reflectivity alloy layer 202 is formed on the electrode layer 201; the material of the high reflectivity alloy layer 202 can be gold, silver, nickel, tin, or an alloy formed with at least two of the four listed metals.

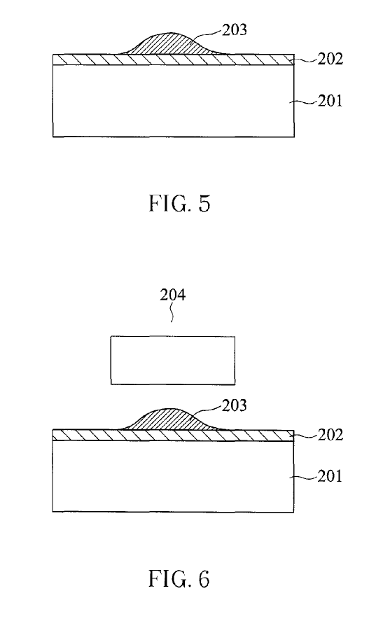

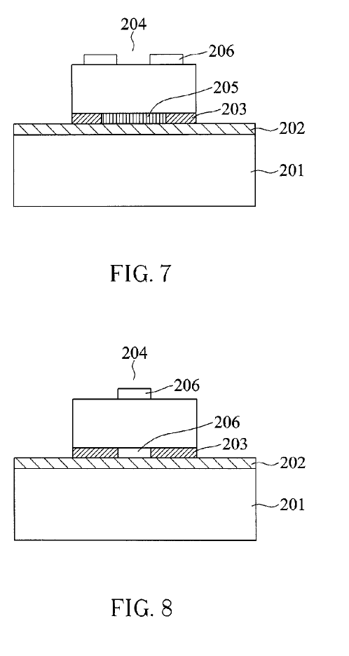

Next, referring to FIG. 5, a portion of the upper surface of the high reflectivity alloy layer 202 is coated with a polymer adhesive 203 to form an adhering point; the polymer adhesive 203 comprises an epoxy resin and at least one of acid anhydride and amine. Subsequently, a chip 204 is fixed to the adhering point and is baked at a preferred temperature of 120 to 180° C. as shown in FIG. 6; the baked chip is shown in FIGS. 7 and 8.

It is to be noted that the chip 204 can be of different forms. Referring to FIG. 7, the chip 204 includes a chip alloy layer 205 and an electrode layer 206, wherein the anode and cathode of the electrode layer 206 are on the same side of the chip 204. Alternately, the chip 204 can include just an electrode layer 206 and the anode and cathode of the electrode layer 206 can be on different sides of the chip 204, as shown in FIG. 8. The material of the chip 204 can mainly be GaN, AlGaN, AlN, GaInN, GaAs, AlInGaP, AlGaInN, InN, GaInAsN, or GaInPN; the chip alloy layer 205 can be gold, silver, nickel, tin, or an alloy formed with at least two of the four listed metals. The range of light and photon energy generated by the chip 204 is between the spectrums of UV light and infrared light.

As a result of the LED packaging method according to a preferred embodiment of the invention, the alloy layer or electrode layer of the chip has a greater contact area with the electrode layer of a package structure, as shown in FIGS. 7 and 8, due to the material property of the adhesive. Thus, the improved conductivity enhances the luminous efficiency, and as well, the adhesive is of a transparent material, which gives better transparency. Moreover, this LED package structure can compete with the package structure of flux eutectic method in electrical property and heat dissipation effect, and is even better than the package structure formed by using silver paste to fix chips thereon; this LED package structure also has a stronger adhesion force.

Take Cree chip as an example. The Cree chip is packaged using the LED packaging method of the invention and then the advantages of this packaging method are explored with respect to the allowable pushing force, the electrical property and heat resistance of the packaged chip, wherein the LED package is of a ceramic type. In the push force test, a micro probe is used to push the fixed chip, and as the pushing force increases, the chip detaches when the force reaches a critical value. The average critical value of the chip fixed by silver paste is 306 grams, whereas the average critical value of the chip fixed by the LED packaging method of the invention is 822 grams, which is more than double that of the chip packaged by the conventional method with silver paste.

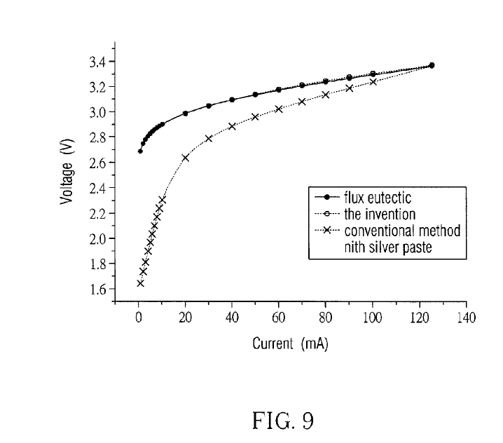

FIG. 9 illustrates a comparison of the electrical property of the LED packaging method of the invention, the conventional packaging method with silver paste, and the flux eutectic packaging method. The x-axis represents the current (mA), and the y-axis represents the voltage (V).

The voltage-current curve of the LED packaging method of the invention is the same as that of the flux eutectic packaging method; the chip property is maintained. On the other hand, the current-voltage curve of the packaging method with the silver paste fails to present the original chip property, especially when the current is small.

It can be seen that the LED packaging method of the invention is superior to the conventional packaging method that fixes chips with silver paste, and has better heat dissipation effect than the flux eutectic packaging method.

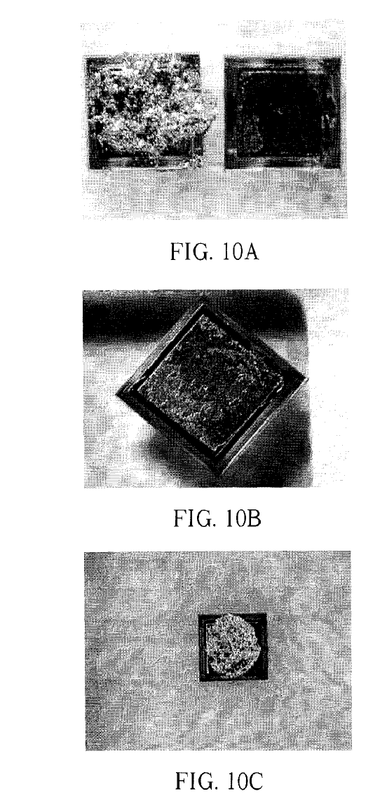

FIGS. 10A, 10B, and 10C illustrate resultant products of the LED packaging method and the conventional packaging method. The left chip in FIG. 10A and the chip in FIG. 10C are chips packaged using the conventional LED packaging method. It can be observed that most of the silver paste is adhered to the chip after the pushing/pulling, which means that the adhesion between the chip and the alloy layer of the package structure is poor and a stronger pushing force is not allowable.

Conversely, the right chip in FIG. 10A and the chip in FIG. 10B, which were packaged using the LED packaging method of the invention, do not have adhesive residues thereon. When looked more closely, some of the metal surfaces on the chip are detached and adhered to the adhesive, which proves that the LED packaging method of the invention enhances the adhesion force of the chips.

While the invention has been described by way of example and in terms of the preferred embodiment, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A LED packaging method, comprising:
forming a high reflectivity alloy layer on an electrode layer of a support;
coating a polymer adhesive on a portion of the upper surface of the high reflectivity alloy layer to form an adhering point, wherein the polymer adhesive includes an epoxy resin and at least one of acid anhydride and amine; and
fixing and baking a chip on the adhering point.

2. The LED packaging method of claim 1, wherein the material of said support comprises at least one selected from the group consisting of iron, copper, aluminum, high polymer composite material, thermosetting composite material, thermoplastic metal composite material, ceramic composite material, carbon fiber composite material and ceramic material substantially composed of clay, cement and glass.

3. The LED packaging method of claim 1, wherein the high reflectivity alloy layer is formed with at least one metal selected from the group consisting of gold, silver, nickel, and tin.

4. The LED packaging method of claim 1, wherein the chip comprises at least one electrode layer, and the anode and the cathode of the electrode layer are on different sides of the chip.

5. The LED packaging method of claim 1, wherein the chip comprises at least one electrode layer, and the anode and the cathode of the electrode layer are on the same side of the chip.

6. The LED packaging method of claim 5, wherein the chip further comprises a chip alloy layer, and the side of the chip with the chip alloy layer is fixed to the adhering point.

7. The LED packaging method of claim 1, wherein the material of the development system of the chip is selected from the group consisting of GaN, AlGaN, AlN, GaInN, GaAs, AlInGaP, AlGaInN, InN, GaInAsN, and GaInPN.

8. The LED packaging method of claim 1, wherein the chip alloy layer is formed with at least one metal selected from the group consisting of gold, silver nickel, and tin.

9. The LED packaging method of claim 1, wherein the range of light and photon energy generated by the chip is between the spectrums of ultraviolet (UV) light and infrared light.

10. The LED packaging method of claim 1, wherein the baking temperature ranges from 120 to 180° C.

11. A LED package structure, comprising:
an electrode layer of a support;
a high reflectivity alloy layer provided on the electrode layer, a portion of the upper surface of the high reflectivity alloy layer being coated with a polymer adhesive for forming an adhering point, wherein the polymer adhesive comprises an epoxy resin and at least one of acid anhydride and amine; and
a chip fixed on the adhering point.

12. The LED package structure of claim 11, wherein the material of said support comprises at least one selected from the group consisting of iron, copper, aluminum, high polymer composite material, thermosetting composite material, thermoplastic metal composite material, ceramic composite material, carbon fiber composite material and ceramic material substantially composed of clay, cement and glass.

13. The LED package structure of claim 11, wherein the high reflectivity alloy layer is formed with at least one metal selected from the group consisting of gold, silver, nickel, and tin.

14. The LED package structure of claim 11, wherein the chip comprises at least one electrode layer, and the anode and cathode of the electrode layer are on different sides of the chip.

15. The LED package structure of claim 11, wherein the chip comprises at least one electrode layer, and the anode and cathode of the electrode layer are on the same side of the chip.

16. The LED package structure of claim 15, wherein the chip further comprises a chip alloy layer and the side of the chip with the chip alloy layer is fixed to the adhering point.

17. The LED package structure of claim 11, wherein the material of the chip is selected from the group consisting of GaN, AlGaN, AlN, GaInN, GaAs, AlInGaP, AlGaInN, InN, GaInAsN, and GaInPN.

18. The LED package structure of claim 11, wherein the chip alloy layer is formed with at least one metal selected from the group consisting of gold, silver, nickel, and tin.

19. The LED package structure of claim 11, wherein the range of light and photon energy generated by the chip is between the spectrums of UV light and infrared light.

20. The LED package structure of claim 11, wherein the side of the chip with the chip alloy layer is fixed to the adhering point by baking, and the baking temperature ranges from 120 to 180° C.
